(19) United States
(12) Patent Application Publication
(10) Pub. No.: US 2024/0035759 A1
(43) Pub. Date: Feb. 1, 2024

(54) METAL FILM, DISPLAY DEVICE, AND MANUFACTURING METHOD THEREOF

(71) Applicant: Shenzhen China Star Optoelectronics Semiconductor Display Technology Co., Ltd., Shenzhen, Guangdong (CN)

(72) Inventor: Rong XIA, Shenzhen, Guangdong (CN)

(21) Appl. No.: 17/753,071

(22) PCT Filed: Jan. 25, 2022
(86) PCT No.: PCT/CN2022/073756

§ 371 Date: Feb. 17, 2022

(30) Foreign Application Priority Data
Jan. 10, 2022 (CN) 202210020562.7

(51) Int. Cl. F28F 21/08; H10K 59/80; B21D 53/04

(52) U.S. Cl. CPC F28F 21/089; H10K 59/8794; B21D 53/04

(57) ABSTRACT

A metal film, a display device, and a manufacturing method thereof are provided. The display device includes a display panel, a metal film, and an adhesive layer. The metal film includes a base layer and a plurality of filaments. The base layer includes a first surface and a second surface opposite to the first surface. The plurality of filaments are formed on the first surface of the base layer, and the second surface of the base layer is adhered to the display panel through the adhesive layer. By providing the metal film with the filaments, an application range and a heat dissipation performance of the display device are improved.

### FIELD OF DISCLOSURE

The present disclosure relates to the field of display technologies, in particular to a metal film, a display device, and a manufacturing method thereof.

### BACKGROUND

Referring to FIG. 1, which shows a schematic diagram of a display device in the prior art. A flexible display device 10 includes a flexible display panel 11, a first adhesive layer 12, and a backplane 13. The first adhesive layer 12 is disposed between the flexible display panel 11 and the backplane 13 for adhering the flexible display panel 11 and the backplane 13. The back panel 13 is used to support the flexible display panel 11. The back plate 13 includes a metal plate 14, a second adhesive layer 15, and a protective layer 16. In the prior art, the metal plate 14 is generally made of stainless steel, which has characteristics of high elasticity and high strength to support the flexible display panel 11. In addition, a plurality of hollow structures are formed on the metal plate 14 to reduce an elastic modulus of the stainless steel, thereby ensuring that the flexible display device 10 can be rolled or folded. However, using the stainless steel metal plate 14 to form the backplate 13 will cause a poor heat dissipation performance of the flexible display device 10.

Accordingly, it is necessary to provide a metal film, a display device, and a manufacturing method thereof to solve the problems in the prior art.

### SUMMARY OF DISCLOSURE

Using the stainless steel metal plate 14 to form the backplate 13 will cause the poor heat dissipation performance of the flexible display device 10. In order to solve the above problems of the prior art, an object of the present disclosure is to provide a metal film, a display device, and a manufacturing method thereof, which can improve the problem of poor heat dissipation performance of the display device.

In order to achieve the above object, the present disclosure provides a metal film including: a base layer and a plurality of filaments. The plurality of filaments are formed on one surface of the base layer.

In some embodiment, the base layer and the plurality of filaments are integrally formed.

In some embodiment, an end of each of the filaments includes a hook structure.

In some embodiment, the metal film is made of aluminum or copper.

In some embodiment, a diameter of a cross section of each of the filaments ranges from 0.05 mm to 1 mm.

The present disclosure also provides a display device, including: a display panel; a metal film including a base layer and a plurality of filaments, where the base layer includes a first surface and a second surface opposite to the first surface, and the plurality of filaments are formed on the first surface of the base layer; and an adhesive layer disposed between the display panel and the metal film, where the second surface of the base layer is adhered to the display panel through the adhesive layer.

In some embodiment, the base layer and the plurality of filaments of the metal film are integrally formed.

In some embodiment, an end of each of the filaments includes a hook structure.

In some embodiment, the display panel includes: a substrate adhered to the second surface of the base layer through the adhesive layer; a display function layer disposed on the substrate; and a polarizer disposed on the display function layer.

In some embodiment, the metal film is made of aluminum or copper.

In some embodiment, a diameter of a cross section of each of the filaments ranges from 0.05 mm to 1 mm.

The present disclosure also provides a manufacturing method of a display device, including: providing a display panel and a base layer, where the base layer includes a first surface and a second surface opposite to the first surface; forming a plurality of filaments on the first surface of the base layer; and adhering the display panel to the second surface of the base layer, where the base layer and the plurality of filaments together form a metal film, and the metal film is configured to support the display panel.

In some embodiment, when the plurality of filaments are formed on the first surface of the base layer, the manufacturing method further includes: forming the plurality of filaments on the first surface of the base layer by a mechanical thread rolling method.

In some embodiment, when the plurality of filaments are formed on the first surface of the base layer, the manufacturing method further includes: forming a patterned layer on the first surface of the base layer; removing a part of the base layer that is not covered by the patterned layer to form a plurality of vertical filaments on the first surface of the base layer; and applying a pressure to the plurality of vertical filaments of the base layer to bend the plurality of vertical filaments, thereby forming the plurality of filaments on the first surface of the base layer.

In some embodiment, an end of each of the filaments includes a hook structure.

In some embodiment, the base layer and the plurality of filaments of the metal film are integrally formed.

In some embodiment, in the step of providing the display panel, the manufacturing method further includes: providing a substrate; disposing a display function layer on the substrate; and disposing a polarizer on the display function layer; where the manufacturing method further includes: disposing an adhesive layer between the substrate and the base layer, and adhering the substrate to the second surface of the base layer through the adhesive layer.

In some embodiment, the metal film is made of aluminum or copper.

In some embodiment, a diameter of a cross section of each of the filaments ranges from 0.05 mm to 1 mm.

In the present disclosure, by providing the metal film with the plurality of filaments, a heat dissipation performance of the display device is improved. Furthermore, the end of the filament of the metal film includes the hook structure, so that the metal film is formed with a hook surface of a hook-and-loop fastener structure. Using a principle of the hook-and-loop fastener, the display device can be attached to an object with a corresponding surface microstructure, thereby increasing an application range. In addition, in comparison with the prior art, the present disclosure prevents the use of a stainless steel plate with multiple hollow structures, which is difficult to manufacture and has low material utilization, thereby greatly reducing the difficulty and cost of production.

### BRIEF DESCRIPTION OF DRAWINGS

The technical solutions and other advantages of the present disclosure will be apparent through the detailed description of specific embodiments of the present disclosure with reference to the accompanying drawings.

FIG. 1 shows a schematic diagram of a display device in the prior art.

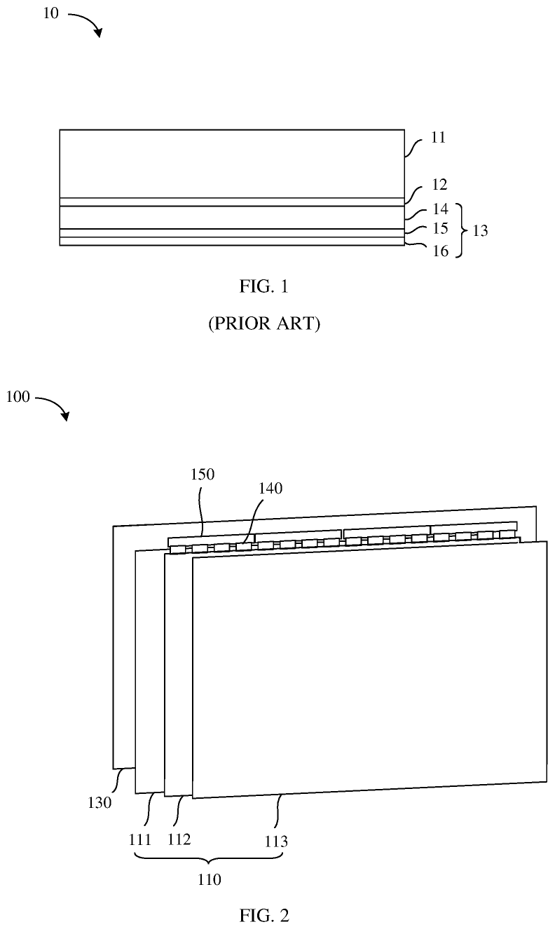

FIG. 2 shows an exploded view of elements of a display device according to an embodiment of the present disclosure.

FIG. 3 shows a cross-sectional view of the display device of FIG. 2.

FIG. 4 shows an enlarged view of a portion A of the display device of FIG. 3.

FIG. 5A to FIG. 5E show a series of schematic diagrams of a display device for illustrating a manufacturing method of the display device according to a first embodiment of the present disclosure.

FIG. 6A to FIG. 6E show a series of schematic diagrams of a display device for illustrating a manufacturing method of the display device according to a second embodiment of the present disclosure.

### DETAILED DESCRIPTION

The technical solutions in the embodiments of the present disclosure will be clearly and completely described below with reference to the accompanying drawings in the embodiments of the present disclosure. Apparently, the described embodiments are only some, but not all, embodiments of the present disclosure. Based on the embodiments in the present disclosure, all other embodiments obtained by those skilled in the art without creative efforts shall fall within a protection scope of the present disclosure.

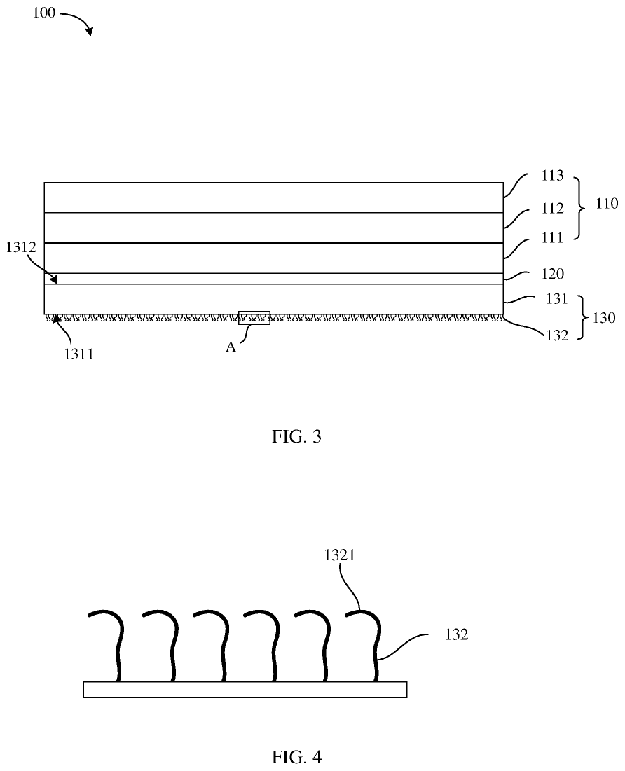

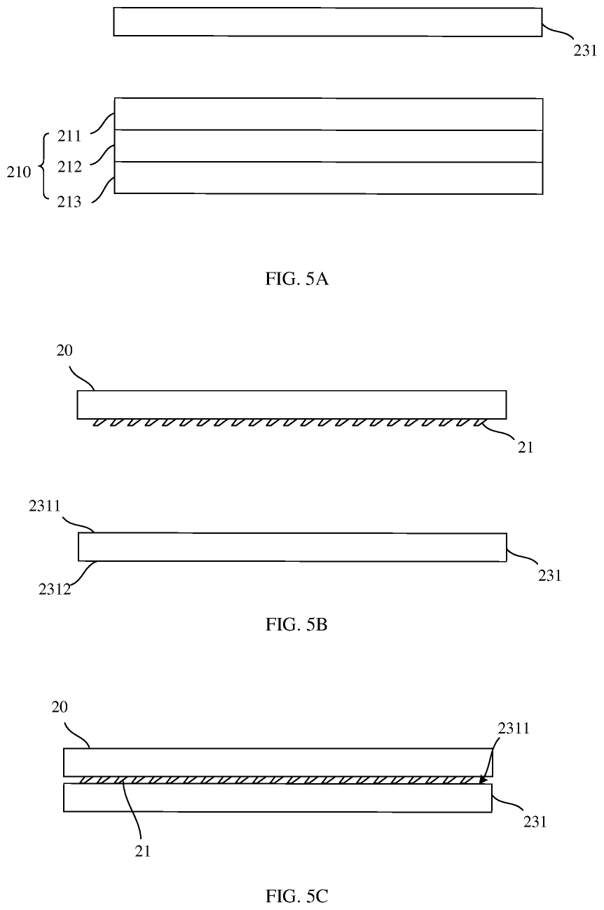

Referring to FIG. 2 and FIG. 3, FIG. 2 shows an exploded view of elements of a display device according to an embodiment of the present disclosure, and FIG. 3 shows a cross-sectional view of the display device of FIG. 2. A display device 100 includes a display panel 110, an adhesive layer 120, a metal film 130, a flexible circuit board 140, and a driving circuit board 150. The adhesive layer 120 is disposed between the display panel 110 and the metal film 130, and is configured to connect the display panel 110 and the metal film 130. Also, the metal film 130 is configured to support the display panel 110. The display panel 110 includes a substrate 111, a display function layer 112, and a polarizer 113. The flexible circuit board 140 and the driving circuit board 150 are disposed on one side of the display function layer 112 and are electrically connected to the display function layer 112. The display function layer 112 is disposed on the substrate 111, and the polarizer 113 is disposed on the display function layer 112.

Alternatively, the display device 100 of the present disclosure may be a flexible display device or a non-flexible display device, including but not limited to a liquid crystal display device, an organic light-emitting diode (OLED) display device, and the like. When the display device 100 is flexible, the display device 100 has characteristics of being bendable and foldable, and the display panel 110 and the metal film 130 are respectively a flexible display panel and a flexible metal film. In addition, when the display device 100 is an OLED display device, the display function layer 112 of the display panel 110 includes OLED elements.

As shown in FIG. 3, the metal film 130 includes a base layer 131 and a plurality of filaments 132. The base layer 131 includes a first surface 1311 and a second surface 1312 opposite to the first surface 1311. The plurality of filaments 132 are formed on the first surface 1311 of the base layer 131. The second surface 1312 of the base layer 131 of the metal film 130 is adhered to the substrate 111 of the display panel 110 through the adhesive layer 120.

In this embodiment, the metal film 130 is made of material with good heat dissipation performance, such as aluminum or copper. The plurality of filaments 132 are formed on the first surface 1311 of the base layer 131 of the metal film 130 by etching or mechanical filament rolling. By controlling a size of the filaments 132, the number of the filaments 132 per unit area can be controlled. Increasing the number of the filaments 132 can effectively increase a heat dissipation area of the metal film 130, so that the display device 100 has good heat dissipation performance. In one embodiment, a diameter of a cross section of each filament 132 ranges from 0.05 mm to 1 mm Preferably, the base layer 131 and the plurality of filaments 132 of the metal film 130 are integrally formed, thereby preventing the plurality of filaments 132 from being easily separated from the base layer 131.

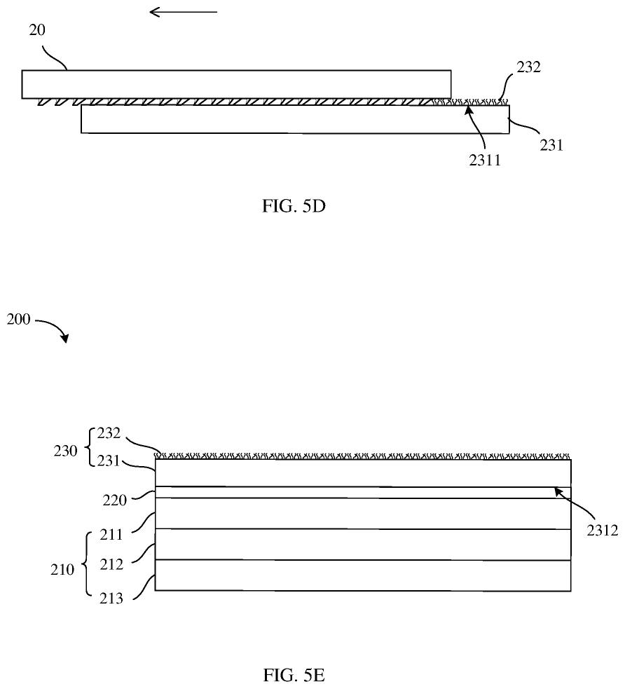

Referring to FIG. 4, which shows an enlarged view of a portion A of the display device of FIG. 3. An end of the filament 132 includes a hook structure 1321, so that the first surface 1311 of the base layer 131 forms a hook surface of a hook-and-loop fastener structure. Using a principle of the hook-and-loop fastener, the display device 100 can be attached to an object with a corresponding surface microstructure, thereby increasing an applications range. Similarly, the display device 100 can also be easily separated from the object. Furthermore, when the display device 100 of the present disclosure is flexible, the display device 100 of the present disclosure can be attached to a curved surface having a corresponding surface microstructure through the metal film 130. In addition, using the hook-and-loop fastener principle, the filaments 132 can also be a loop surface structure opposite to the hook surface, and can also be attached to an object with a corresponding surface microstructure, which is not specifically limited in the present disclosure. In comparison with the prior art, the present disclosure prevents the use of a stainless steel plate with multiple hollow structures, which is difficult to manufacture and has low material utilization, thereby greatly reducing the difficulty and cost of production.

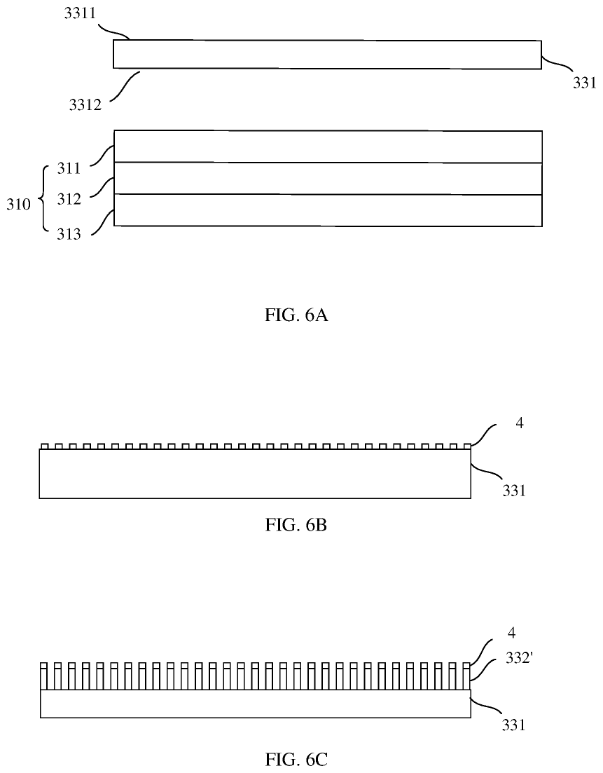

Referring to FIG. 5A to FIG. 5E, which show a series of schematic diagrams of a display device for illustrating a manufacturing method of the display device according to a first embodiment of the present disclosure.

First, as shown in FIG. 5A, a display panel 210 and a base layer 231 are provided. The display panel 210 includes a substrate 211, a display function layer 212, and a polarizer 213. The substrate 211 is configured to be adhered to the base layer 231. The display function layer 212 is disposed on the substrate 211, and the polarizer 213 is disposed on the display function layer 212. Alternatively, the display device of the present disclosure may be a flexible display device or a non-flexible display device. When the display device is flexible, the display device has characteristics of being bendable and foldable. In addition, when the display device is an OLED display device, the display function layer 212 of the display panel 210 includes OLED elements.

Next, a plurality of filaments 232 is formed on a first surface 2311 of the base layer 231 by a mechanical thread rolling method. Specifically, as shown in FIG. 5B, the base layer 231 includes a first surface 2311 and a second surface 2312 opposite to the first surface 2311. The base layer 231 is placed in a surface treatment machine 20. The surface treatment machine 20 includes a plurality of burrs 21. As shown in FIG. 5C, the surface treatment machine 20 is controlled to move toward the base layer 231, and the burrs 21 are brought into contact with the base layer 231. Then, the burrs 21 of the surface treatment machine 20 are controlled to pierce into the first surface 2311 of the base layer 231. In some embodiments, the burrs 21 pierce the base layer 231 to a depth of about 0.1 to 1 mm. As shown in FIG. 5D, the base layer 231 is fixed, and the surface treatment machine 20 is controlled to move along the first surface 2311 of the base layer 231 to form the plurality of filaments 232 on the first surface 2311 of the base layer 231. With the movement of the surface treatment machine 20, a length of the filament 232 gradually increases, so that an end of the filament 232 extends along a surface of the burr 21 until it interferes with a base of the burr 21. Restricted by the base of the burrs 21, the ends of the filaments 232 are bent into a hook structure.

Finally, as shown in FIG. 5E, the display panel 210 is adhered to the second surface 2312 of the base layer 231, thereby forming the display device 200. Specifically, the display panel 210 is adhered to the base layer 231 through the adhesive layer 220. The base layer 231 and the plurality of filaments 232 together form a metal film 230. The metal film 230 is configured to support the display panel 210.

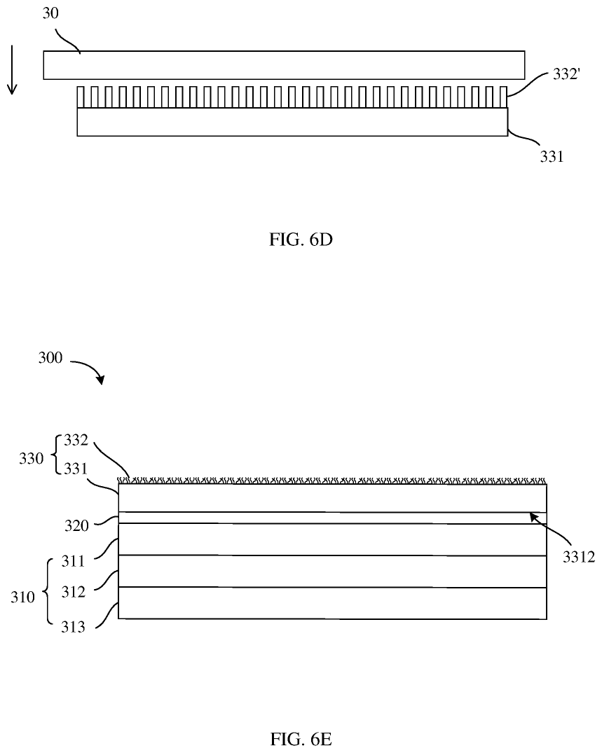

In this embodiment, the metal film 230 is made of material with good heat dissipation performance, such as aluminum or copper. By controlling a size of the filament 232, the number of the filaments 232 per unit area can be controlled. Increasing the number of the filaments 232 can effectively increase a heat dissipation area of the metal film 230, so that the display device 200 has good heat dissipation performance. In one embodiment, a diameter of a cross section of each filament 232 ranges from 0.05 mm to 1 mm. Furthermore, since the base layer 231 and the plurality of filaments 232 of the metal film 230 are integrally formed, the plurality of filaments 232 are prevented from being easily separated from the base layer 231. On the other hand, the end of the filament 232 includes the hook structure, so that the first surface 2311 of the base layer 231 forms a hook surface of a hook-and-loop fastener structure. Using a principle of the hook-and-loop fasteners, the display device 200 can be attached to an object with a corresponding surface microstructure. Similarly, the display device 200 can also be easily separated from the object. Furthermore, when the display device 200 of the present disclosure is flexible, the display device 200 of the present disclosure can be attached to a curved surface having a corresponding surface microstructure through the metal film 230. Therefore, in the field of application, the display device 200 of the present disclosure has an extremely high breadth. Referring to FIG. 6A to FIG. 6E, which show a series of schematic diagrams of a display device for illustrating a manufacturing method of the display device according to a second embodiment of the present disclosure.

First, as shown in FIG. 6A, a display panel 310 and a base layer 331 are provided. The base layer 331 includes a first surface 3311 and a second surface 3312 opposite to the first surface 3311. The display panel 310 includes a substrate 311, a display function layer 312, and a polarizer 313. The substrate 311 is configured to be adhered to the second surface 3312 of the base layer 331. The display function layer 312 is disposed on the substrate 311, and the polarizer 313 is disposed on the display function layer 312. Alternatively, the display device of the present disclosure may be a flexible display device or a non-flexible display device. When the display device is flexible, the display device has characteristics of being bendable and foldable. In addition, when the display device is an OLED display device, the display function layer 312 of the display panel 310 includes organic light-emitting diode (OLED) elements.

Next, a plurality of filaments 332 are formed on the first surface 3311 of the base layer 331. Specifically, as shown in FIG. 6B, a patterned layer 4 is formed on the first surface 3311 of the base layer 331 through a photomask and a corresponding photoetching process. As shown in FIG. 6C, the base layer 331 is placed in a chemical etching machine, and a part of the base layer 331 that is not covered by the patterned layer 4 is removed by chemical solution, so as to form a plurality of vertical filaments 332′ on the first surface 3311 of the base layer 331. As shown in FIG. 6D, the patterned layer 4 is removed, and the etched base layer 331 is placed in a pressing machine 30. The plurality of vertical filaments 332′ of the base layer 331 is pressurized by the pressing machine 30 to bend the plurality of vertical filaments 332′, thereby forming the plurality of filaments 332 on the first surface 3311 of the base layer 331.

Finally, as shown in FIG. 6E, the substrate 311 of the display panel 310 is adhered to the second surface 3312 of the base layer 331 through an adhesive layer, thereby forming the display device 300. Specifically, the display panel 310 is adhered to the base layer 331 through the adhesive layer 320. The base layer 331 and the plurality of filaments 332 together form a metal film 330. The metal film 330 is configured to support the display panel 310.

In this embodiment, the metal film 330 is made of material with good heat dissipation performance, such as aluminum or copper. By controlling a size of the filament 332, the number of the filaments 332 per unit area can be controlled. Increasing the number of the filaments 332 can effectively increase a heat dissipation area of the metal film 330, so that the display device 300 has good heat dissipation performance. In one embodiment, a diameter of a cross section of each filament 332 ranges from 0.05 mm to 1 mm. Furthermore, since the base layer 331 and the plurality of filaments 332 of the metal film 330 are integrally formed, the plurality of filaments 332 are prevented from being easily separated from the base layer 331. On the other hand, the end of the filament 332 includes the hook structure, so that the first surface 3311 of the base layer 331 forms a hook surface of a hook-and-loop fastener structure. Using a principle of the hook-and-loop fasteners, the display device 300 can be attached to an object with a corresponding surface microstructure. Similarly, the display device 300 can also be easily separated from the object. Furthermore, when the display device 300 of the present disclosure is flexible, the display device 300 of the present disclosure can be attached to a curved surface having a corresponding surface microstructure through the metal film 330. Therefore, in the field of application, the display device 300 of the present disclosure has an extremely high breadth.

In conclusion, in the present disclosure, by providing the metal film with the plurality of filaments, the heat dissipation performance of the display device is improved. Furthermore, the end of the filament of the metal film includes the hook structure, so that the metal film is formed with a hook surface of a hook-and-loop fastener structure. Using a principle of the hook-and-loop fastener, the display device can be attached to an object with a corresponding surface microstructure, thereby increasing an application range. In addition, in comparison with the prior art, the present disclosure prevents the use of a stainless steel plate with multiple hollow structures, which is difficult to manufacture and has low material utilization, thereby greatly reducing the difficulty and cost of production.

The metal film, the display device, and the manufacturing method thereof of the embodiments of the present disclosure are described above in detail. The principles and implementations of the present disclosure are described herein by using specific embodiments. The descriptions of the above embodiments are only used to help understand the technical solutions and core ideas of the present disclosure. Those of ordinary skill in the art should understand that they can still make modifications to the technical solutions described in the foregoing embodiments, or perform equivalent replacements to some of the technical features. However, these modifications or substitutions do not make the essence of the corresponding technical solutions deviate from the scope of the technical solutions of the embodiments of the present disclosure.

What is claimed is:

1. A metal film, comprising: a base layer and a plurality of filaments, wherein the plurality of filaments are formed on one surface of the base layer.

2. The metal film according to claim 1, wherein the base layer and the plurality of filaments are integrally formed.

3. The metal film according to claim 1, wherein an end of each of the filaments comprises a hook structure.

4. The metal film according to claim 1, wherein the metal film is made of aluminum or copper.

5. The metal film according to claim 1, wherein a diameter of a cross section of each of the filaments ranges from 0.05 mm to 1 mm.

6. A display device, comprising:
a display panel;
a metal film comprising a base layer and a plurality of filaments, wherein the base layer comprises a first surface and a second surface opposite to the first surface, and the plurality of filaments are formed on the first surface of the base layer; and
an adhesive layer disposed between the display panel and the metal film, wherein the second surface of the base layer is adhered to the display panel through the adhesive layer.

7. The display device according to claim 6, wherein the base layer and the plurality of filaments of the metal film are integrally formed.

8. The display device according to claim 6, wherein an end of each of the filaments comprises a hook structure.

9. The display device of claim 6, wherein the display panel comprises:
a substrate adhered to the second surface of the base layer through the adhesive layer;
a display function layer disposed on the substrate; and
a polarizer disposed on the display function layer.

10. The display device according to claim 6, wherein the metal film is made of aluminum or copper.

11. The display device according to claim 6, wherein a diameter of a cross section of each of the filaments ranges from 0.05 mm to 1 mm.

12. A manufacturing method of a display device, comprising:
providing a display panel and a base layer, wherein the base layer comprises a first surface and a second surface opposite to the first surface;
forming a plurality of filaments on the first surface of the base layer; and
adhering the display panel to the second surface of the base layer, wherein the base layer and the plurality of filaments together form a metal film, and the metal film is configured to support the display panel.

13. The manufacturing method of the display device according to claim 12, wherein when the plurality of filaments are formed on the first surface of the base layer, the manufacturing method further comprises:
forming the plurality of filaments on the first surface of the base layer by a mechanical thread rolling method.

14. The manufacturing method of the display device according to claim 12, wherein when the plurality of filaments are formed on the first surface of the base layer, the manufacturing method further comprises:
forming a patterned layer on the first surface of the base layer;
removing a part of the base layer that is not covered by the patterned layer to form a plurality of vertical filaments on the first surface of the base layer; and
applying a pressure to the plurality of vertical filaments of the base layer to bend the plurality of vertical filaments, thereby forming the plurality of filaments on the first surface of the base layer.

15. The manufacturing method of the display device according to claim 12, wherein an end of each of the filaments comprises a hook structure.

16. The manufacturing method of the display device according to claim 12, wherein the base layer and the plurality of filaments of the metal film are integrally formed.

17. The manufacturing method of the display device according to claim 12, wherein in the step of providing the display panel, the manufacturing method further comprises:
providing a substrate;
disposing a display function layer on the substrate; and
disposing a polarizer on the display function layer;
wherein the manufacturing method further comprises: disposing an adhesive layer between the substrate and the base layer, and adhering the substrate to the second surface of the base layer through the adhesive layer.

18. The manufacturing method of the display device according to claim 12, wherein the metal film is made of aluminum or copper.

19. The manufacturing method of a display device according to claim 12, wherein a diameter of a cross section of each of the filaments ranges from 0.05 mm to 1 mm.
